(19) United States
(12) Patent Application Publication
(10) Pub. No.: US 2011/0200064 A1
(43) Pub. Date: Aug. 18, 2011

(54) Optical device and optical apparatus

(75) Inventor: Noriyuki Banno, Miyagi (JP)

(73) Assignee: Sony Corporation, Tokyo (JP)

(21) Appl. No.: 12/929,274

(22) Filed: Jan. 12, 2011

(30) Foreign Application Priority Data
Feb. 15, 2010 (JP) 2010-030220

(51) Int. Cl. H01S 5/02

(52) U.S. Cl. 372/44.01

(57) ABSTRACT

An optical device includes: an optical element having a first light-emitting region in the vicinity of a first surface and a first metal layer in contact with at least a region of the first surface which does not face the first light-emitting region; a support body disposed on the side of the optical element toward which the first surface faces; and a fuse-bonding layer disposed between the first surface and the support body and in a region which does not face the first light-emitting region, the fuse-bonding layer bonding the first metal layer and the support body.

### BACKGROUND OF THE INVENTION

1. Field of the Invention

The present invention relates to an optical device including a plurality of optical elements contained in the same package and an optical apparatus having such an optical device.

2. Description of the Related Art

Semiconductor lasers utilizing nitride type group III-V compound semiconductors (typical such compounds include GaN, AlGaN, and GaInN crystals, and such semiconductors will therefore be referred to as “GaN type semiconductors) provide oscillation wavelengths around 400 nm (e.g., 405 nm) which is regarded as the wavelength limit of optical discs which can be recorded and reproduced using existing optical systems. For this reason, such semiconductors are used as light sources of recording/reproducing apparatus of next-generation optical discs such as Blu-ray discs.

Most of recording/reproducing apparatus for next-generation optical discs accommodate a multiplicity of disc formats in order to satisfy demands in the market. Specifically, those apparatus are allows recording and reproduction of not only optical discs of the next generation but also existing optical discs such as DVDs (Digital versatile discs), CDs (Compact Discs), CD-Rs (CD Recordables), CD-RW (CD Rewritables), and MDs (Mini Discs). Similarly, most of DVD recording/reproducing apparatus which are rapidly spreading in recent years allow recording and reproduction of CDs, CD-Rs, and the like which have been introduced earlier than DVDs.

Research and development is being actively carried out to provide multi-wavelength lasers to be used as light sources of multi-format compatible optical disc apparatus. Such lasers are obtained by containing a semiconductor laser generating light in a 400 nm band and a semiconductor laser generating light in a 600 nm band (e.g., light having a wavelength of 660 um) to be used for recording and reproduction of DVDs or light in a 700 nm band (e.g., light having a wavelength of 780 nm) to be used for recording and reproduction of CDs and CD-Rs in a single package. The use of a multi-wavelength laser makes it possible to simplify the configuration of an optical system including an objective lens, a beam splitter and the like for recording and reproducing various types of optical disc through a reduction in the number of components of such an optical system. As a result, an optical disc apparatus can be provided with a small size and a small thickness at a low cost.

Since both of a semiconductor laser in the 600 nm band and a semiconductor laser in the 700 nm band are formed on a GaAs substrate, those lasers can be consolidated in a single chip (or monolithically formed). While a substrate made of sapphire, SiC, ZnO or GaN is used as the substrate of a semiconductor laser in the 400 nm band, a GaAs substrate cannot be used. For this reason, a multi-wavelength laser including a 400 nm band semiconductor laser according to the related art is what is called a hybrid type laser which is obtained by, for example, stacking a 400 nm band semiconductor laser 210 having a GaN substrate 211 and a monolithic semiconductor laser 220 having a GaAs substrate 221 for generating light in the 600 nm band and the 700 nm band on a support substrate 230, as shown in FIG. 15 (for example, see JP-A-2001-230502 (Patent Document 1)).

In some proposals on the fabrication of hybrid multi-wavelength laser, it is suggested to use flip chip bonding for bonding the two semiconductor lasers (for example, see JP-A-11-340587 (Patent Document 2)).

In the above-described hybrid multi-wavelength laser according to the related art, since wires W1 and W2 are bonded to a bottom surface of the GaN substrate 211 to electrically connect the substrate to a package (not shown), the semiconductor laser 210 must have great dimensions. Only a few substrate manufactures have been able to produce a GaN substrate of high quality, and the manufacture of such a substrate has been technically difficult. Therefore, a GaN substrate is expensive. Thus, a problem has existed in that an increase in the size of a semiconductor laser 210 can directly result in an increase in the material cost of the same.

As shown in FIG. 16, the semiconductor lasers 210 and 220 may be stacked in the reverse order to facilitate wire bonding with the size of the semiconductor laser 210 kept small. In this case, however, when the semiconductor laser 220 is mounted such that the GaAs substrate side of the laser faces the support substrate 230, since the GaAs substrate has low heat conductivity, radiating performance is degraded, which makes it difficult to keep the life of the multi-wavelength laser sufficiently long. On the contrary, when the semiconductor laser 220 is mounted such that the GaAs substrate side thereof faces the semiconductor laser 210, amounting step for allowing independent driving at each wave band becomes difficult to perform.

The applicant has proposed an approach in which the semiconductor lasers 210 and 220 are stacked on the support substrate 230 in the same order as shown in FIG. 15 with the size of the semiconductor laser 210 kept small and in which eaves-like projecting parts of the semiconductor laser 220 are supported by bumps (not shown). The approach allows the material cost of the laser to be kept low and to achieve high radiating performance.

### SUMMARY OF THE INVENTION

According to the approach proposed by the applicant, a fuse-bonding layer (not shown) is used to bond the semiconductor layer 210 and the semiconductor laser 220 to each other. The fuse-bonding layer has a linear expansion coefficient greater than the linear expansion coefficient of the material used for the semiconductor lasers 210 and 220. Therefore, when the temperature of the semiconductor lasers 210 and 220 and the fuse-bonding layer increases as the semiconductor lasers 210 and 220 are driven, the semiconductor lasers 210 and 220 and the fuse-bonding layer undergo thermal expansion depending on the respective linear expansion coefficients. Tensile distortion attributable to the difference between the linear expansion coefficients occurs in the regions of the semiconductor lasers 210 and 220 where the lasers are secured to each other by the fuse-bonding layer. As a result, the band structures of the semiconductor lasers 210 and 220 change. Since TM mode polarization components consequently increase, the polarization ratio of the TE mode can decrease.

Such a decrease in the polarization ratio can be problematic especially when the multi-wavelength laser is used as a light source of an optical disc device. Specifically, in the optical disc device, a λ/4 plate is interposed between the light source and an optical disc to suppress noise attributable to return light, and signal light from the optical disc is guided to a light-receiving element through the λ/4 plate. Since TE mode components in the signal light from the optical disc are primarily detected by the light receiving element, when the polarization ratio of the TE mode decreases as a result of a temperature rise, the intensity of light that the light-receiving element can detect, decreases.

Under the circumstance, it is desirable to provide an optical device in which a decrease in the polarization ratio of the TE mode can be prevented and an optical apparatus having such an optical device.

According to one embodiment of the invention, there is provided an optical device including an optical element having a first light-emitting region in the vicinity of a first surface and a first metal layer in contact with at least a region of the first surface which does not face the first light-emitting region. The optical device includes a support body disposed on the side of the optical element toward which the first surface faces. Further, the optical device includes a fuse-bonding layer disposed between the first surface and the support body and in a region which does not face the first light-emitting region, the fuse-bonding layer bonding the first metal layer and the support body. An optical apparatus according to the embodiment includes the above-described optical device as a light source.

In the optical device and the optical apparatus according to the embodiment of the invention, the fuse-bonding layer for bonding the first metal layer and the support body to each other is provided in a region which does not face the first light-emitting region. Thus, even when the optical element and the fuse-bonding layer undergo a temperature rise as the optical element is driven and consequently undergo thermal expansion according to their respective linear expansion coefficients, the generation of distortion attributable to a difference between the linear expansion coefficients can be prevented at the first light-emitting region.

According to another embodiment of the invention, there is provided an optical device including an optical element having a light-emitting region in the vicinity of a first surface and a metal layer in contact with at least a region of the first surface facing the light-emitting region. The optical device includes a support body disposed on the side of the optical element toward which the first surface faces. The optical device further includes a fuse-bonding layer disposed between the first surface and the support body and in at least a region facing the light-emitting region, the fuse-bonding layer bonding the metal layer and the support body. Further, the optical device includes an anti-distortion layer provided between the region of the first surface facing the light-emitting region and the fuse-bonding layer, the anti-distortion layer including a material having a linear expansion coefficient smaller than the linear expansion coefficient of the metal layer. An optical apparatus according to this embodiment of the invention includes the optical device according to this embodiment of the invention as a light source.

In the optical device and the optical apparatus according to this embodiment of the invention, the anti-distortion layer including a material having a linear expansion coefficient smaller than the linear expansion coefficient of the metal layer is provided between the region of the first surface facing the light-emitting region and the fuse-bonding layer. Thus, even when the optical element and the fuse-bonding layer undergo a temperature rise as the optical element is driven and consequently undergo thermal expansion according to their respective linear expansion coefficients, the generation of distortion attributable to a difference between the linear expansion coefficients can be prevented at the light-emitting region.

In the optical devices and optical apparatus according to the embodiments of the invention, even when the optical element and the fuse-bonding layer undergo thermal expansion according to their respective linear expansion coefficients, the generation of distortion attributable to a difference between a difference the linear expansion coefficients is prevented at the light-emitting region. As a result, a decrease in the TE mode polarization ratio can be suppressed. Since a decrease in the TE mode polarization ratio can be suppressed as thus described, when the optical device according to the first or second embodiment is used as a light source of an optical disc apparatus, it is possible to suppress a reduction in the intensity of light that a light-receiving element can detect.

### BRIEF DESCRIPTION OF THE DRAWINGS

FIG. 1 is a sectional view of a semiconductor laser device according to a first embodiment of the invention showing an exemplary configuration thereof;

FIG. 2 is a sectional view of an exemplary laser structure for defining the light-emitting region in FIG. 1;

FIG. 3 is a sectional view of another exemplary laser structure for defining the light-emitting region in FIG. 1;

FIG. 4 is a sectional view of a first modification of the semiconductor laser device shown in FIG. 1;

FIG. 5 is a sectional view of a second modification of the configuration of the semiconductor laser device shown in FIG. 1;

FIG. 6 is a sectional view of a third modification of the configuration of the semiconductor laser device shown in FIG. 2;

FIG. 7 is a sectional view of a semiconductor laser device according to a second embodiment of the invention showing an exemplary configuration thereof;

FIG. 8 is a sectional view of a first modification of the configuration of the semiconductor laser device shown in FIG. 7;

FIG. 9 is a sectional view of a second modification of the configuration of the semiconductor laser device shown in FIG. 7;

FIG. 10 is a sectional view of a semiconductor laser device according to a third embodiment of the invention showing an exemplary configuration thereof;

FIG. 11 is a sectional view of a semiconductor laser device according to a fourth embodiment of the invention showing an exemplary configuration thereof;

FIG. 12 is a sectional view showing another exemplary configuration of the semiconductor laser device shown in FIG. 10;

FIG. 13 is a sectional view showing another exemplary configuration of the semiconductor laser device shown in FIG. 11;

FIGS. 14A and 14B show an exemplary schematic configuration of an optical disc recording/reproducing apparatus according to an exemplary application of the embodiments of the invention;

FIG. 15 is a sectional view of a semiconductor laser device according to the related art showing an exemplary configuration of such a device; and

FIG. 16 is a sectional view of a semiconductor laser device according to the related art showing another exemplary configuration of such a device.

### DESCRIPTION OF PREFERRED EMBODIMENTS

Embodiments of the invention will now be described in detail with reference to the drawings. The following items will be described in the order listed.

1. First Embodiment (The embodiment includes no fuse-bonding layer in a region facing a light-emitting region)

2. Modification of First Embodiment

3. Second Embodiment (The embodiment includes an anti-distortion layer in a region facing a light emitting region)

4. Modification of Second Embodiment

5. Third Embodiment (The embodiment is a three-wavelength laser including no fuse-bonding layer in a region facing a light-emitting region.)

6. Fourth Embodiment (The embodiment is a three-wavelength laser including an anti-distortion layer in a region facing a light-emitting region.)

7. Applications (The optical disc recording/reproducing apparatus)

### First Embodiment

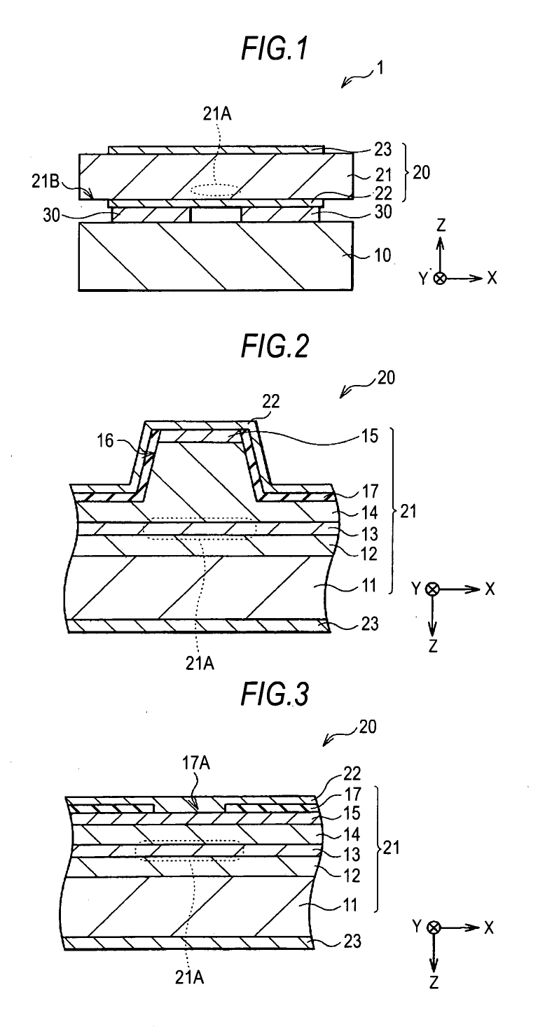

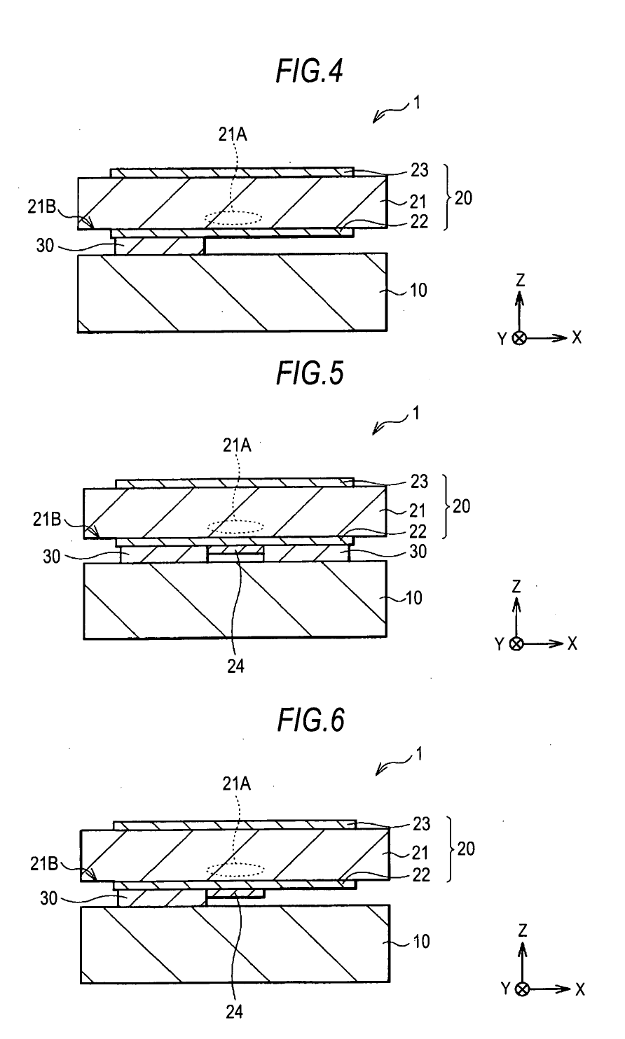

FIG. 1 shows an example of a sectional structure of a semiconductor laser device 1 (optical device) according to a first embodiment of the invention. The semiconductor laser device 1 includes a semiconductor laser 20 (optical element) disposed on a support body 10. A fuse-bonding layer 30 is provided between the support body 10 and the semiconductor laser 20 for boding the support body 10 and the semiconductor laser 20 to each other.

The support body 10 is disposed on a side of the semiconductor laser 20 where a surface 21B (first surface) is provided as will be described later. For example, the support body 10 may be a heat sink or sub-mount supporting the semiconductor laser 20, and the support body may alternatively be an optical element such as a semiconductor laser. The heat sink or sub-mount functions as a radiating member for dissipating heat generated at the semiconductor laser 20. For example, a heat sink may be formed from a metal such as Cu, and a sub-mount may alternatively be formed from Si or AlN.

For example, the semiconductor laser 20 includes a laser section 21 having a light-emitting region 21A (first light-emitting region) provided in the vicinity of a surface 21B of the section facing the support body 10. For example, the semiconductor laser 20 further includes an electrode 22 (which is a metal layer) provided on the surface 21B of the laser section 21 and an electrode 23 provided on a surface of the laser section 21 facing the surface 21B. The electrode 22 is in contact with the surface 21B of the laser section 21 in a region of the surface facing the light-emitting region 21A and also in a region surrounding the region facing the region 21A (a region which does not face the light-emitting region 21A).

As shown in FIGS. 2 and 3, the laser section 21 includes, for example, a substrate 11, a clad layer 12, an active layer 13, a clad layer 14, and a contact layer 15. The clad layer 12, the active layer 13, the clad layer 14, and the contact layer 15 are stacked on the substrate 11 in the order listed to form a double hetero structure. The light-receiving region 21A is a region of the active layer 13 into which a current flowing through the electrodes 22 and 23 is injected and from which light having a wavelength in accordance with the band gap of the active layer 13 is emitted as a result of the current injection. For example, when the laser section 21 has an index guide structure as shown in FIG. 2, a top surface of a ridge stripe 16 in the form of a convex (a top surface of the contact layer 15) is in contact with the electrode 22, and side surfaces and skirts of the ridge stripe 16 are covered by an insulation layer 17. Therefore, the light-emitting region 21A is formed in a part of the active layer 13 facing the convex ridge stripe 16 in this case. When the laser section 21 has a gain guide structure as shown in FIG. 3, a part of the top surface of the contact layer 15 exposed in an opening 17A of the insulation layer 17 is in contact with the electrode 22, and the remaining part of the top surface of the contact layer 15 is covered by the insulation layer 17. Therefore, the light-emitting region 21A is formed in a part of the active layer 13 facing the opening 17A of the insulation layer 17 in this case.

When the semiconductor laser 20 is a semiconductor laser emitting laser light in, for example, a 400 nm band (e.g., laser light having a wavelength of 405 nm) from the light-emitting region 21A thereof, the clad layer 12, the active layer 13, the clad layer 14, and the contact layer 15 are formed from, for example, a GaN type compound semiconductor. In this case, a GaN substrate having a heat conductivity as high as, for example, about 130 W/(m·K) is used as the substrate 11 of the semiconductor laser 20. When the semiconductor laser 20 is a semiconductor laser emitting laser light in, for example, a 600 nm band (e.g., laser light having a wavelength of 650 nm) from the light-emitting region 21A thereof, the clad layer 12, the active layer 13, the clad layer 14, and the contact layer 15 are formed from, for example, an AlGaInP type compound semiconductor. When the semiconductor laser 20 is a semiconductor laser emitting laser light in, for example, a 700 nm band (e.g., laser light having a wavelength of 780 nm) from the light-emitting region 21A thereof, the clad layer 12, the active layer 13, the clad layer 14, and the contact layer 15 are formed from, for example, an AlGaAs type compound semiconductor. When the semiconductor laser 20 is formed from an AlGaInP type or AlGaAs type compound semiconductor, a GaAs substrate having a heat conductivity as low as, for example, about 55 W/(m·K) is used as the substrate 11 of the semiconductor laser 20.

The electrodes 22 and 23 function as electrodes for injecting a current into the light-emitting region 21A, and the electrodes also function as radiating member for dissipating heat generated at the semiconductor laser 20. For example, the electrodes 22 and 23 are formed from a metal material having a high conductivity. For example, the electrode 22 is formed from Ti, Pt, Au, or Pd. The electrode 22 may be a multi-layer body formed from a plurality of metal materials. For example, the electrode may be formed by stacking layers of Ti, Pt, and Au in the order listed from the side of the laser section 21. The electrode 23 may be formed from an alloy of Au and Ge, Ni, or Au. Alternatively, the electrode 23 may be formed from Ti, Pt, or Au. The electrode 23 may be a multi-layer body formed from a plurality of metal materials. For example, the electrode may be formed by stacking layers of an alloy of Au and Ge, Ni, or Au in the order listed from the side of the laser section 21. Alternatively, the electrode 23 may be formed by stacking layers of Ti, Pt, and Au in the order listed from the side of the laser section 21. For example, the insulation layer 17 is formed from SiO₂, SiN, or the like.

The fuse-bonding layer 30 will now be described. The fuse-bonding layer 30 is formed in a region which is located between the electrode 22 and the support body 10 and which does not face the light emitting region 21A. For example, the fuse-bonding layer 30 may be provided in the form of stripes. The fuse-bonding layer is located between the electrode 22 and the support body 10 and on both sides of the region facing the light-emitting region 21A, as shown in FIG. 1. The fuse-bonding layer 30 is formed in contact with regions of the surface of the electrode 22 which do not face the light-emitting region 21A. The fuse-bonding layer is also in contact with regions of the surface of the support body 10 facing the semiconductor laser 20 which doe not face the light-emitting region 21A. That is, the fuse-bonding layer 30 is not in contact with the surface of the electrode 22 in the region of the surface facing the light-emitting region 21A. The fuse-bonding layer 30 is not in contact with the surface of the support body 10 provided to face the semiconductor laser 20 in the region of the support body facing the light-emitting region 21A. For example, the region which is located between the electrode 22 and the support body 10 and which faces the light-emitting region 21A may be an air gap. Although not shown, this region may be filled with a material having a linear expansion coefficient equal to or smaller than that of the support body 10 and the semiconductor laser 20.

When the fuse-bonding layer 30 is provided only for securing the semiconductor laser 20 on the support body 10, the fuse-bonding layer 30 may be formed from a material which is either electrically conductive or insulating. That is, the fuse-bonding layer 30 may be formed from an insulating adhesive such as a heat-curing resin or a UV-curing region, in this case. Alternatively, the layer may be formed from a conductive bonding material such as solder. For example, solder types usable as the layer include Sn, Au—Sn alloys, Zn—Sn alloys, and Ag—Sn alloys.

When a lead-out electrode (not shown) is provided on the surface of the support body 10 and the fuse-bonding layer 30 is used as a wiring to provide conduction between the electrode 22 and the lead-out electrode, the fuse-bonding layer 30 may be formed from a conductive bonding material such as solder. The above-described solder materials may be used in this case.

There is no particular restriction on the linear expansion coefficient of the fuse-bonding layer 30. The layer may have a linear expansion coefficient greater than that of the support body 10 and the semiconductor laser 20. The linear expansion coefficient of the layer may alternatively be equal to or smaller than that of the support body 10 and the semiconductor laser 20. When any of the above-described solder material is used as the fuse-bonding layer 30, the linear expansion coefficient of the fuse-bonding layer 30 is greater than the linear expansion coefficient of the support body 10 and the semiconductor laser 20.

In the present embodiment of the invention, the fuse-bonding layer 30 for bonding the electrode 22 and the support body 10 to each other is provided in regions which do not face the light-emitting region 21A. As a result, even when the semiconductor laser 20 and the fuse-bonding layer 30 undergo a temperature rise as the semiconductor laser 20 is driven and consequently undergo thermal expansion according to their respective linear expansion coefficients, the generation of distortion attributable to a difference between the linear expansion coefficients can be prevented at the light-emitting region 21A. Thus, a decrease in the TE mode polarization ratio can be prevented. Further, since a decrease in the TE mode polarization ratio can be prevented, when the semiconductor laser device 1 is used, for example, as a light source of an optical disc apparatus (not shown), a reduction in the intensity of light detectable with the light-receiving element (not shown) can be prevented.

### Modification of First Embodiment

In the above-described embodiment, the electrode 22 is in contact with the surface 21B of the laser section 21 in a region of the surface facing the light-emitting region 21A and in a region surrounding the region facing the region 21A. When the semiconductor laser 20 has a current injection electrode other than the electrode 22, the electrode 22 may be in contact with the surface 21B of the laser section 21 only in a region of the surface which does not face the light-emitting region 21A.

In the above-described embodiment, the fuse-bonding layer 30 is located between the electrode 22 and the support body 10 and provided in the form of stripes on both sides of the region facing the light-emitting region 21A, as shown in FIG. 1. For example, the fuse-bonding layer 30 may alternatively be provided in the form of a stripe only on one side of the region facing the light-emitting region 21A.

In the above-described embodiment and modification, the fuse-bonding layer 30 is not in contact with the surface of the electrode 22 in the region facing the light-emitting region 21A. The manufacturing process of the semiconductor laser device preferably involves a mechanism for preventing the fuse-bonding layer 30 from spreading into the region. For example, such a mechanism may involve an anti-bonding layer 24 having low wettability with respect to the fuse-bonding layer 30 provided on the surface of the region of the electrode 22 facing the light-emitting region 21A, as shown in FIGS. 5 and 6. For example, the anti-bonding layer 24 includes a metal having low wettablity such as Pt or an insulating material such as SiO₂ or SiN.

In the above-described embodiment and modification, the fuse-bonding layer 30 is not in contact with the surface of the support body 10 facing the semiconductor laser 20 in a region of the surface facing the light-emitting region 21A. The manufacturing process of the semiconductor laser device preferably involves a mechanism for preventing the fuse-bonding layer 30 from spreading into the region. For example, such a mechanism may involve an anti-bonding layer having low wettability with respect to the fuse-bonding layer 30 provided on the surface of the region of the support body 10 facing the semiconductor laser 20 in a region of the surface facing the light-emitting region 21A, although not shown. The anti-bonding layer includes, a metal having low wettablity such as Pt or an insulating material such as SiO₂ or SiN.

### Second Embodiment

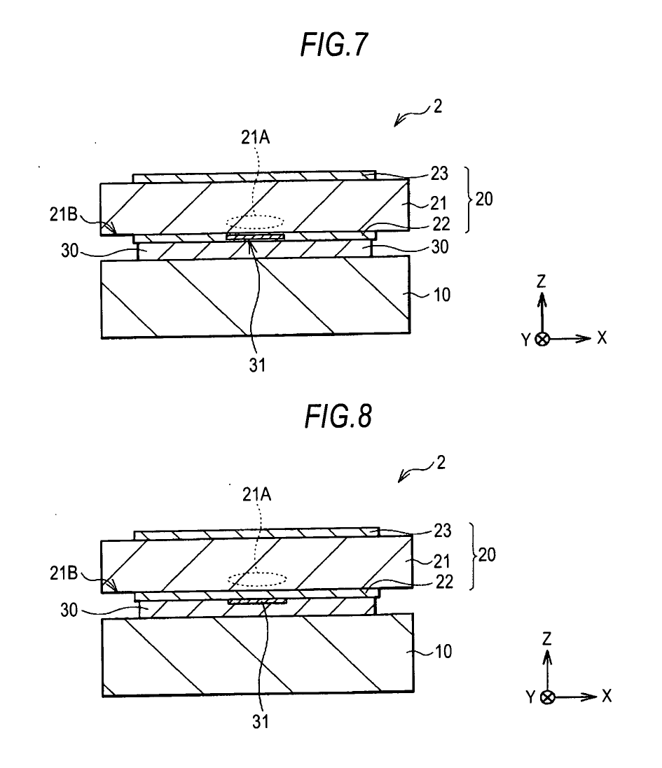

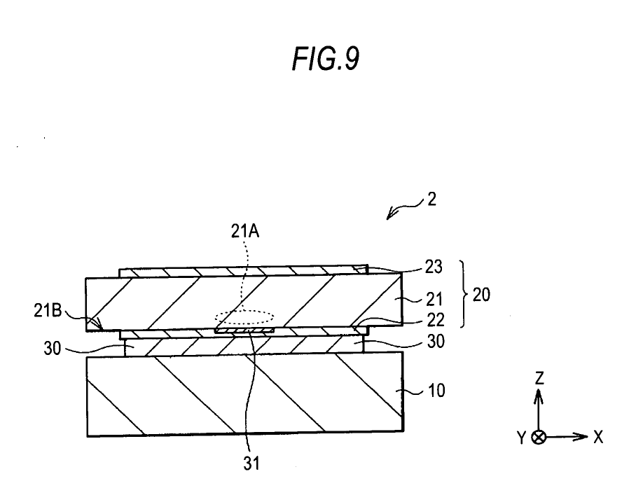

FIG. 7 shows an example of a sectional structure of a semiconductor laser device 2 (optical device) according to a second embodiment of the invention. The semiconductor laser device 2 is identical in configuration to the semiconductor laser device 1 of the above-described embodiment in that a semiconductor laser 20 (optical device) is disposed on a support body 10 with a fuse-bonding layer 30 interposed between them. On the contrary, the semiconductor laser device 2 is different in configuration from the semiconductor laser device 1 of the above-described embodiment in that the fuse-bonding layer 30 is disposed in a region which is located between the support body 10 and the semiconductor laser 20 and which faces at least a light-emitting region 21A. Further, the semiconductor laser device 2 is also different from the semiconductor laser device 1 of the above-described embodiment in that an anti-distortion layer 31 is provided between the region of a surface 21B of a laser section 21 facing the light-emitting region 21A and the fuse-bonding layer 30. The following description will focus on the differences from the above-described embodiment and will omit the similarity to the above-described embodiment as occasion demands.

In the present embodiment, the fuse-bonding layer 30 is provided between the support body 10 and the semiconductor laser 20 and in a region facing the light-emitting region 21A, and the fuse-bonding layer extends around the region facing the region 21A. The fuse-bonding layer 30 is in contact with the surface of the electrode 22 facing the support body 10 in a region of the electrode surface facing the light-emitting region 21A and in a region surrounding the region facing the region 21A. The fuse-bonding layer 30 is also in contact with the surface of the support body 10 facing the semiconductor layer 20 in a region of the support body surface facing the light-emitting region 21A and in a region surrounding the region facing the region 21A.

The anti-distortion layer 31 may be formed inside the electrode 22, for example, as shown in FIG. 7. Although there is no particular restriction on the shape of the anti-distortion layer 31, the layer may have the same shape as the shape of the light-emitting region 21A. Although there is no particular restriction on the size of the anti-distortion layer 31, the laser has a size greater than the size of the light-emitting region 21A. The anti-distortion layer 31 includes a material having a linear expansion coefficient smaller than the linear expansion coefficient of the electrode 22, and the layer preferably includes a material having a linear expansion coefficient equal to or smaller than the linear expansion coefficient of the laser section 21. Thus, the anti-distortion layer 31 suppresses the generation of distortion attributable to a difference between the linear expansion coefficients of the fuse-bonding layer 30 and the electrode 22. For example, the anti-distortion layer 31 includes SiN which has a linear expansion coefficient of about 1.7 ppm/° C. or SiO₂ which has a linear expansion coefficient of about 0.5 ppm/° C.

In the present embodiment, the anti-distortion layer 31 is provided between the region of the surface 21B of the laser section 21 facing the light-emitting region 21A and the fuse-bonding layer 20. As a result, even when the semiconductor laser 20 and the fuse-bonding layer 30 undergo a temperature rise as the semiconductor laser 20 is driven and consequently undergo thermal expansion according to their respective linear expansion coefficients, the generation of distortion attributable to the difference between the linear expansion coefficients is prevented at the light-emitting region 21A. Thus, a decrease in the TE mode polarization ratio can be prevented. Further, since a decrease in the TE mode polarization ratio can be prevented, for example, when the semiconductor laser device 2 is used as a light source of an optical disc apparatus (not shown), it is possible to prevent a decrease in the intensity of light that a light-receiving element of the apparatus (not shown) can detect.

### Modification of Second Embodiment

While the anti-distortion layer 31 of the second embodiment is formed inside the electrode 22, the layer may alternatively be formed between the electrode 22 and the fuse-bonding layer 30 as shown in FIG. 8. Further, the layer 31 may alternatively be formed between the electrode 22 and the surface 21B of the laser section 21. When the anti-distortion layer 31 is formed between the electrode 22 and the surface 21B of the laser section 21, the size of the anti-distortion layer 31 is preferably somewhat smaller than the size of the light-emitting region 21A.

### Third Embodiment

### [Configuration]

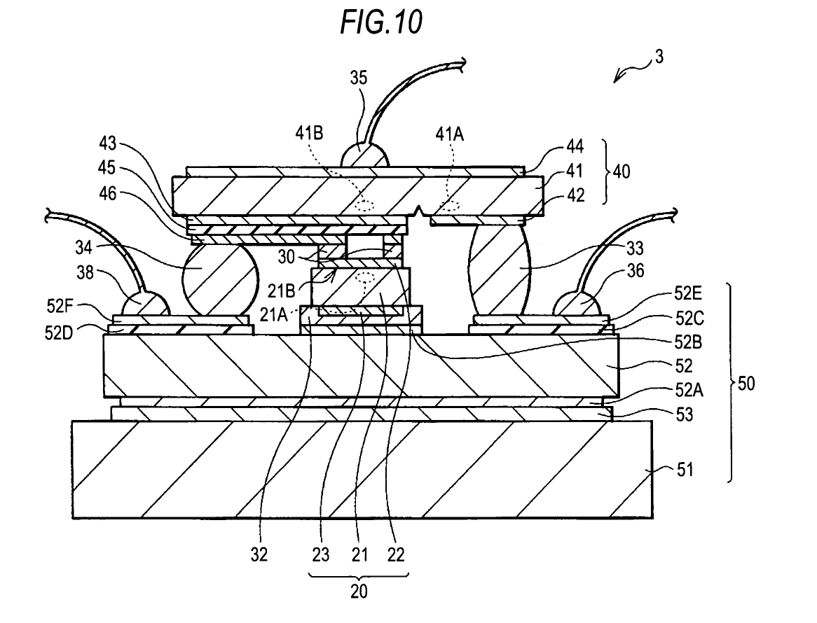

FIG. 10 shows an example of a sectional structure of a semiconductor laser device 3 (optical device) according to a third embodiment of the invention. The semiconductor laser device 3 is preferably used as a light source of an optical disc apparatus (optical apparatus) for recording and reproducing optical discs.

The semiconductor laser device 3 is provided by stacking a semiconductor laser 20 and a semiconductor laser 40 in the order listed on a support base 50, and the device functions as a multi-wavelength laser. The semiconductor lasers 20 and 40 are semiconductor lasers in the form of chips, and the semiconductor laser 40 has a lateral width (a width of the laser in a direction orthogonal to the direction of a resonator of the same) greater than the lateral width of the semiconductor laser 20. The semiconductor lasers 20 and 40 are overlapped such that their respective end faces (not shown) on a light-exiting side thereof are disposed on the same plane. Rear end faces (not shown) of the semiconductor lasers 20 and 40 may be disposed on the same plane, and the rear end faces may alternatively be disposed in plane different from each other. When the rear end faces of the semiconductor lasers 20 and 40 are disposed in the same plane, the resonator lengths of the semiconductor lasers 20 and 40 are equal to each other. When the rear end faces of the semiconductor lasers 20 and 40 are disposed in different planes, the resonator lengths of the semiconductor lasers 20 and 40 are different from each other.

The semiconductor laser 20 is a semiconductor laser which emits laser light in, for example, a 400 nm band (e.g., laser light having a wavelength of 405 nm) from a region (a light-emitting point) on the end face on the light-exiting side thereof associated with a light-emitting region 21A, and the laser is formed from a GaN type compound semiconductor. The semiconductor laser 20 employs a GaN substrate which has a heat conductivity as high as about 130 W/(m·K). The GaN substrate functions as a heat sink for dissipating heat generated in the semiconductor lasers 20 and 40. The semiconductor laser 20 includes an electrode 23 provided on a bottom surface of the semiconductor laser 20 (surface facing the GaN substrate) and an electrode 22 provided on a top surface of the semiconductor laser 20 (surface facing the semiconductor laser 40).

The semiconductor laser 40 is a monolithic multi-wavelength laser which includes two types of semiconductor laser structures for emitting laser light in, for example, a 600 nm band (e.g., laser light having a wavelength of 650 nm) and laser light in, for example, a 700 nm band (e.g., laser light having a wavelength of 780 nm) from regions (light-emitting points) of an end face on a light-exiting side thereof associated with two light-emitting regions 41A and 41B. The semiconductor laser 40 is disposed on the semiconductor laser 20 and a support base 50 in a so-called junction-down mode such that the two light emitting points are disposed close to the light-emitting point of the semiconductor laser 20. For example, the semiconductor laser 40 is disposed on the semiconductor laser 20 and the support base 50 such that the light emitting point corresponding to the light-emitting regions 41B and the light emitting point corresponding to the light-emitting regions 21A are disposed close to each other. The laser structure for the 600 nm band is formed from an AlGaInP type compound semiconductor. The laser structure for the 700 nm band is formed from an AlGaAs type compound semiconductor. In the semiconductor laser 40, a GaAs substrate having a heat conductivity as low as about 55 W/(m·K) is used. In the present embodiment, heat generated in the semiconductor laser 40 is transmitted to the support base 50 through the semiconductor laser 20 and bumps 33 and 34 instead of being transmitted to the GaAs substrate.

In the semiconductor laser 40, a GaAs type laser section 41 including two light-emitting regions 41A and 41B is provided on the GaAs substrate. Two electrodes 42 and 43 and a lead-out electrode 46 are provided on a bottom side of the semiconductor laser 40 (the side of the laser facing the semiconductor laser 20). The electrode 43 and the lead-out electrode 46 are stacked with an insulation layer 45 interposed between them and are therefore electrically isolated from each other. The electrode 43 is disposed closer to the semiconductor laser 40 than the lead-out electrode 46 is. An electrode 44 is provided on a top side of the semiconductor laser 40 (the side of the laser facing the GaAs substrate). A wire 35 is bonded to the electrode 44. The electrode 42 functions as a laser electrode on the side of device where the light-emitting region 41A is provided, and the electrode 43 on the side of the device where the light-emitting region 41B is provided. The electrode 44 functions as an electrode to be shared by the lasers on both sides of the device where the light-emitting regions 41A and 41B are provided. For example, the electrodes 42, 43, and 44 and the lead-out electrode 46 include a metal material having a high heat conductivity such as gold.

The semiconductor lasers 20 and 40 are bonded to each other through a fuse-bonding layer 30 interposed between them. As shown in FIG. 10, the electrode 22 on the semiconductor laser 20 and the lead-out electrode 46 on the semiconductor laser 40 are bonded and electrically connected to each other by the fuse-boding layer 30. The semiconductor laser 20 is bonded to the support base 50 (or a sub-mount 52 which will be described later) through a fuse-bonding layer 32.

The semiconductor laser 40 is bonded to the support base 50 (or the sub-mount 52 which will be described later) through the fuse-bonding layer 30, the semiconductor laser 20, and the fuse-bonding layer 32 interposed between them. The semiconductor laser 40 is also bonded to the support base 50 through bumps 33 and 34 interposed between them. As described above, the lateral width of the semiconductor laser 20 is smaller than the lateral width of the semiconductor laser 40, and the semiconductor laser 40 extends beyond the semiconductor laser 20 in the form of eaves in in-plane directions of the sectional view of the device that is taken in the direction in which the lasers are stacked. The parts of the semiconductor laser 40 extending beyond the semiconductor laser 20 in the in-plane directions are bonded to the support base 50 (or the sub-mount 52 which will be described later) through the bumps 33 and 34 and another bump which is not shown. Specifically, the electrode 42 of the semiconductor laser 40 is bonded to the support base 50 (or a lead-out electrode 52E which will be described later) through the bump 33, and the lead-out electrode 46 of the semiconductor laser 40 is bonded to the support base 50 (or a lead-out electrode 52F which will be described later) through the bump 34. Further, the electrode 43 of the semiconductor laser 40 is bonded to the support base 50 (or a lead-out electrode which is not shown later) through the other bump which is not shown.

Let us assume that the semiconductor laser 40 corresponds to the support body 10 and that the surface of the lead-out electrode 46 corresponds to the surface of the support body 10 facing the semiconductor laser 20. Then, the description of the fuse-bonding layer 30 in the first embodiment equally applies to the present embodiment in terms of the position of the fuse-bonding layer, bonded regions, and the material of the fuse-bonding layer. For example, the fuse-bonding layer 32 is formed from the same material as the fuse-bonding layer 30. The bumps 33 and 34 may be formed by solder.

The support base 50 is formed by bonding a heat sink 51 and a sub-mount 52 through a fuse-boning layer 53. The heat sink 51 functions as a radiating member for dissipating heat generated at the semiconductor lasers 20 and 40, and it is formed from a metal such as Cu. The heat sink 51 is electrically connected to an external power source which is not shown, and the heat sink therefore has the function of electrically connecting the semiconductor laser 20 to the external power source.

The sub-mount 52 maintains heat conductivity to the heat sink 51 to prevent a temperature rise at the chips when the chips are driven, thereby keeping the life of the device sufficiently long. For example, the sub-mount is formed from Si or AlN. On a surface of the sub-mount 52 facing the semiconductor laser 20, there is provided a lead-out electrode 52E which is bonded to the bump 33 and a wire 36 and a lead-out electrode 52F which is bonded to the bump 34 and a wire 38. On the surface of the sub-mount 52 facing the semiconductor laser 20, there is provided another lead-out electrode (not shown) which is bonded to the above-described bump and another wire (both of which are not shown). The bumps 33 and 34 are disposed on the surface of the sub-mount 52 with respective insulation layers 52C and 52D interposed between them, and the bumps are therefore electrically isolated from the sub-mount 52. Similarly, the above-described bump (not shown) is also disposed on the surface of the sub-mount 52 with an insulation layer (not shown) interposed between them, and the bump is electrically isolated from the sub-mount 52.

Preferably, at least Au is exposed on top surfaces of the lead-out electrodes 52E and 52F. The reason is that the exposed Au allows the bumps 33 and 34 to be reliably bonded to the lead-out electrodes 52E and 52F when the bumps 33 and 34 are made of solder. For example, the lead-out electrodes 52E and 52F have a structure in which layers of Al, Ni, and Au are stacked in the order listed starting from the side thereof sub-mount 52.

### [Operations]

Operations of the semiconductor laser device 3 of the present embodiment will now be described. In the semiconductor laser device 3, a voltage from the power source is applied between the electrodes 22 and 23 of the semiconductor laser 20 through the wire 38 and a wire (not shown) electrically connected to the heat sink 51. Thus, laser light in the 400 nm band is emitted from a light-emitting point (not shown) on an end face of the laser on a light-exiting side thereof associated with the light-emitting region 21A. Similarly, a voltage from the power source is supplied through the wires 35 and 36 to be applied between the electrodes 42 and 44 provided in the laser structure for emitting laser light in the 700 nm band. Thus, laser light in the 700 nm band is emitted from a light-emitting point (not shown) on an end face of the laser on a light-exiting side thereof associated with the light-emitting region 41A. Similarly, a voltage from the power source is supplied through the wire 35 and a wire (not shown) electrically connected to the electrode 32 to be applied between the electrodes 43 and 44 provided in the laser structure for emitting laser light in the 600 nm band. Thus, laser light in the 600 nm band is emitted from a light-emitting point (not shown) on the end face of the laser on the light-exiting side thereof associated with the light-emitting region 41B. That is, laser light in any of the 400 nm, 600 nm, and 700 nm bands is emitted from the semiconductor laser device 3.

### [Advantage]

In the present embodiment, as described above, the semiconductor laser 20 having high radiating performance is provided closer to the support base 50, and the periphery of the semiconductor laser 40 is connected to the support base 50 through the bumps 33, 34, and the like which have high heat conductivity. Thus, heat generated at the semiconductor laser 40 having relatively low heat radiating performance can be efficiently led to the support base 50. As a result, when the semiconductor laser device 1 is used as, for example, a light source of an optical disc apparatus (not shown), it is possible to prevent a reduction in the intensity of light that a light-receiving element (not shown) can detect. The device of the present embodiment can be manufactured at a low cost because the semiconductor laser 20 has small dimensions.

In the present embodiment, the fuse-bonding layer 30 for bonding the electrode 22 and the support body 10 to each other is provided in regions which do not face the light-emitting region 21A. Therefore, even when the semiconductor laser 20 and the fuse-bonding layer 30 undergo a temperature rise as the semiconductor laser 20 is driven and consequently undergo thermal expansion according to their respective linear expansion coefficients, the generation of distortion attributable to a difference between the linear expansion coefficients can be prevented at the light-emitting region 21A. As a result, a decrease in the TE mode polarization ratio of the device can be suppressed. Since a decrease in the TE mode polarization ratio can be suppressed, when the semiconductor laser device 3 is used as, for example, a light source of an optical disc apparatus (not shown), it is possible to prevent a reduction in the intensity of light that a light-receiving element (not shown) can detect.

### Fourth Embodiment

### [Configuration]

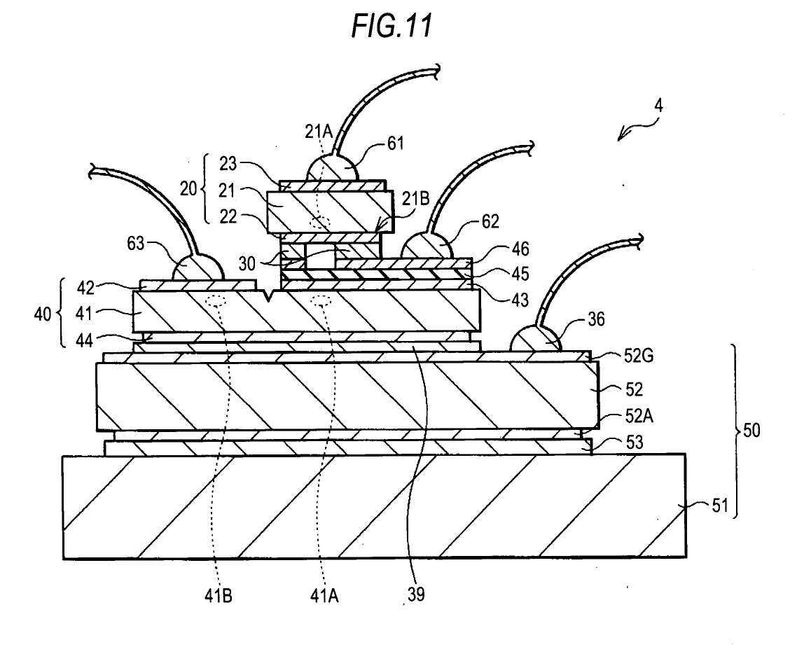

FIG. 11 shows an example of a sectional structure of a semiconductor laser device 4 (optical device) according to a fourth embodiment of the invention. Like the semiconductor laser device 3, the semiconductor laser device 4 is preferably used as a light source of an optical disc apparatus (optical device) for recording and reproducing optical discs.

The semiconductor laser device 4 is provided by stacking a semiconductor laser 40 and a semiconductor laser 20 in the order listed on a support base 50. The device is different in configuration from the semiconductor laser device 3 of the third embodiment primarily in the order in which the semiconductor lasers 20 and 40 are stacked.

The semiconductor laser 20 is mounted on the semiconductor laser 40 and the support base 50 in the so-called junction down mode such that one light-emitting point of the laser is disposed close to two light-emitting points of the semiconductor laser 40. The semiconductor laser 20 is bonded to the support base 50 (or a sub-mount 52) through a fuse-bonding layer 30, the semiconductor laser 40, and a fuse-boding layer 39 interposed between them. An electrode 23 of the semiconductor laser 20 is bonded to a wire 61, and an electrode 22 of the semiconductor laser 20 is electrically connected to a wire 62 through the fuse-bonding layer 30 and a lead-out electrode 46. The semiconductor laser 40 is bonded to the support base 50 (or the sub-mount 52) through the fuse-bonding layer 39. The electrode 44 of the semiconductor laser 40 is electrically connected to a wire 64 through the fuse-bonding layer 39 and a lead-out electrode 52G formed on a surface of the sub-mount 52 facing the semiconductor laser 40. The electrode 42 of the semiconductor laser 40 is bonded to the wire 63, and an electrode 43 of the semiconductor laser 40 is bonded to a wire which is not shown.

### [Operations]

Operations of the semiconductor laser device 4 of the present embodiment will now be described. In the semiconductor laser device 4, a voltage from the power source is applied between the electrodes 22 and 23 of the semiconductor laser 20 through the wires 61 and 62. Thus, laser light in the 400 nm band is emitted from a light-emitting point (not shown) on an end face of the laser on a light-exiting side thereof associated with a light-emitting region 21A. Similarly, a voltage from the power source is supplied through the wires 63 and 64 to be applied between the electrodes 42 and 44 which are provided in a laser structure for emitting laser light in the 700 nm band. Thus, laser light in the 700 nm band is emitted from a light-emitting point (not shown) on an end face of the laser on a light-exiting side thereof associated with a light-emitting region 41B. Similarly, a voltage from the power source is supplied through a wire (not shown) and the wire 64 to be applied between the electrodes 43 and 44 provided in a laser structure for emitting laser light in the 600 nm band. Thus, laser light in the 600 nm band is emitted from a light-emitting point (not shown) on the end face of the laser on the light-exiting side thereof associated with a light-emitting region 41A. That is, laser light in any of the 400 nm, 600 nm, and 700 nm bands is emitted from the semiconductor laser device 4.

### [Advantage]

In the present embodiment, the fuse-bonding layer 30 for bonding the electrode 22 and the support body 10 is provided in regions which do not face the light-emitting region 21A. Therefore, even when the semiconductor laser 20 and the fuse-bonding layer 30 undergo a temperature rise as the semiconductor laser 20 is driven and consequently undergo thermal expansion according to their respective linear expansion coefficients, the generation of distortion attributable to a difference between the linear expansion coefficients can be prevented at the light-emitting region 21A. As a result, a decrease in the TE mode polarization ratio of the device can be suppressed. Since a decrease in the TE mode polarization ratio can be suppressed, when the semiconductor laser device 4 is used as, for example, a light source of an optical disc apparatus (not shown), it is possible to prevent a reduction in the intensity of light that a light-receiving element (not shown) can detect.

### Modification of Third and Fourth Embodiments

In the above-described third and fourth embodiments of the invention, the fuse-bonding layer 30 is not in contact with the surface of the electrode 22 in the region of the surface facing the light-emitting region 21A. The manufacturing process of the semiconductor laser device preferably involves a mechanism for preventing the fuse-bonding layer 30 from spreading into the surface. For example, an anti-bonding layer 24 as shown in FIGS. 5 and 6 may be provided as such a mechanism.

In the above-described third, fourth embodiments and their modifications of the invention, the fuse-bonding layer 30 is not in contact with the surface of the support body 10 facing the semiconductor region 20 in the region of the surface facing the light-emitting region 21A. The manufacturing process of the devices preferably involves a mechanism for preventing the fuse-bonding layer 30 from spreading into such a surface. Such a mechanism may involve an anti-bonding layer having low wettability with respect to the fuse-bonding layer 30 provided on the surface support body 10 facing the semiconductor laser 20 in the region of the surface facing the light-emitting region 21A, although not shown. For example, the anti-bonding layer includes a metal having low wettablity such as Pt or an insulating material such as SiO₂ or SiN.

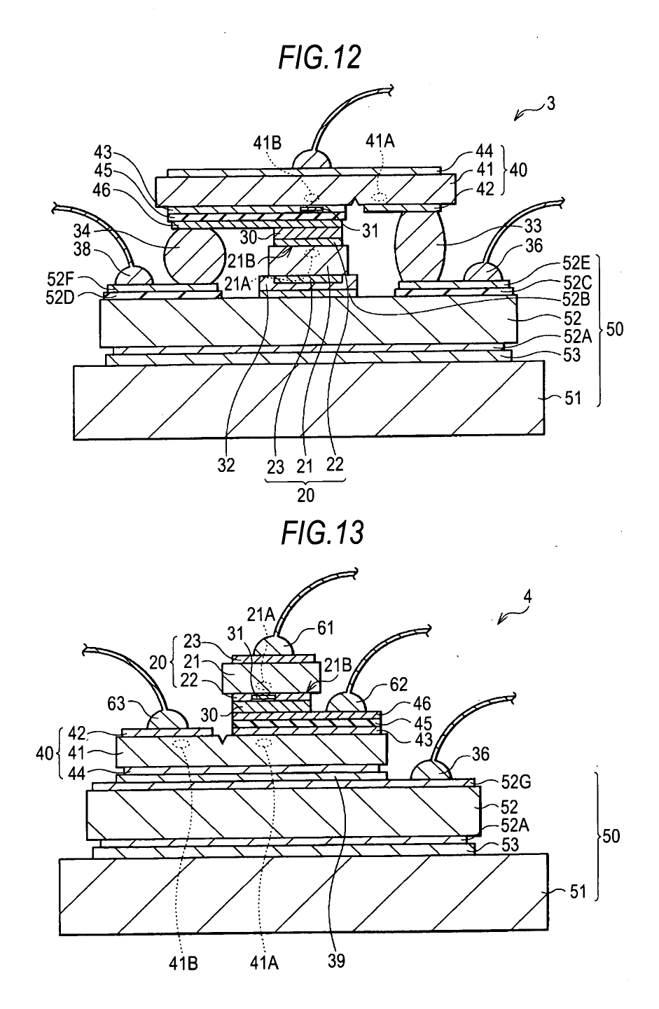

The above-described third, fourth embodiments and their modifications are examples in which a fuse-bonding layer 30 is disposed between a support body 10 and a semiconductor laser 20 and in regions which do not face a light-emitting region 21A. Alternatively, the fuse-bonding layer 30 may be disposed between the support body 10 and the semiconductor laser 20 and at least in a region facing the light-emitting region 21A, as shown in FIGS. 12 and 13. In this case, however, an anti-distortion layer 31 must be provided between a region of a surface 21B of a laser section 21 facing the light-emitting region 21A and the fuse-bonding layer 30.

In a modification of the embodiments, the fuse-bonding layer 30 is provided between the semiconductor laser 20 and the semiconductor laser 40 and in a region facing the light-emitting region 21A and in a region surrounding the opposite region. The fuse-bonding layer 30 is in contact with the surface of the electrode 22 facing the semiconductor laser 40 in the region of the surface facing the light-emitting region 21A and in the region surrounding the opposite region. The fuse-bonding layer is also in contact with the surface of the semiconductor laser 40 facing the semiconductor laser 20 in a region of the surface facing the light-emitting region 21A and in a region surrounding the region facing the region 21A. For example, an anti-distortion layer 31 is formed inside the electrode 22 as shown in FIGS. 12 and 13. Thus, the anti-distortion layer 31 prevents the generation of distortion attributable to a difference between the linear expansion coefficients of the fuse-bonding layer 30 and the electrode 22. For example, the anti-distortion layer 31 includes SiN which has a linear expansion coefficient of about 1.7 ppm/° C. or SiO₂ which has a linear expansion coefficient of about 0.5 ppm/° C.

In the present modification, the anti-distortion layer 31 is provided between the region of the surface 21B of the laser section 21 facing the light-emitting region 21A and the fuse-bonding layer 30. Therefore, even when the semiconductor laser 20 and the fuse-bonding layer 30 undergo a temperature rise as the semiconductor laser 20 is driven and consequently undergo thermal expansion according to their respective linear expansion coefficients, the generation of distortion attributable to a difference between the linear expansion coefficients can be prevented at the light-emitting region 21A. As a result, a decrease in the TE mode polarization ratio of the device can be suppressed. Since a decrease in the TE mode polarization ratio can be suppressed, when the semiconductor laser device 4 according to the modification is used as, for example, a light source of an optical disc apparatus (not shown), it is possible to prevent a reduction in the intensity of light that a light-receiving element (not shown) can detect.

### <Applications>

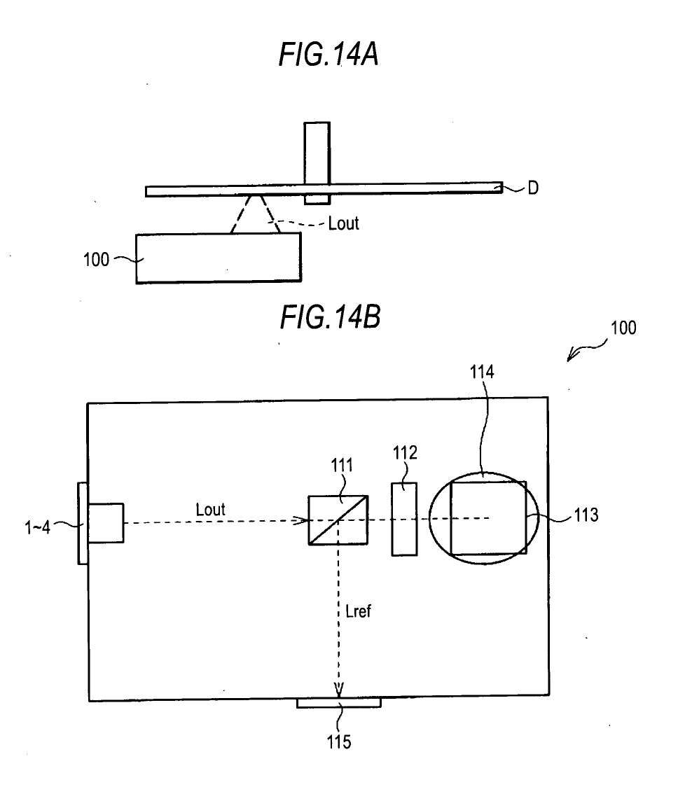

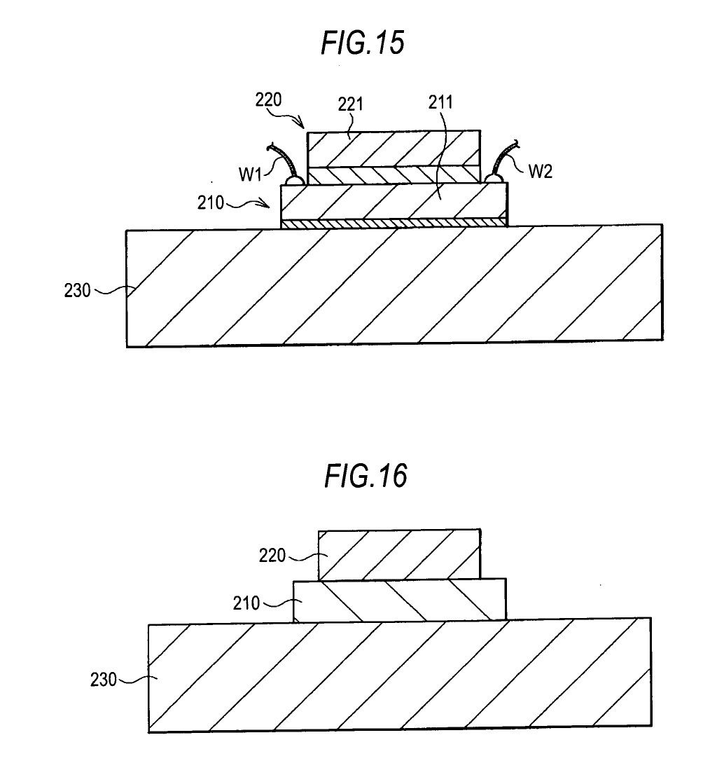

A description will now be made on exemplary applications of the semiconductor laser devices 1 to 4 according to the above-described embodiments and the modifications thereof. An optical disc recording/reproducing apparatus according to an exemplary application reproduces information recorded on an optical disc D and records information in the optical disc D utilizing light having a predetermined wavelength. FIGS. 14A and 14B show an exemplary schematic configuration of an optical disc recording/reproducing apparatus 100 according to the exemplary application. The optical disc recording/reproducing apparatus 100 includes any of the semiconductor laser devices 1 to 4 and an optical system for guiding emitted light Lₒᵤₜ having a predetermined wavelength emitted by any of the semiconductor laser devices 1 to 4 to an optical disc D and reading out signal light (reflected light L_{ref}) from the optical disc D. For example, the optical system includes a beam splitter (PBS) 111, a λ/4 plate 112 for suppressing return light noise, an upward deflecting mirror 113, an objective lens 114, and a signal light detector 115 including a light-receiving element and a signal light reproducing circuit (both of which are not shown).

In the optical disc recording/reproducing apparatus 100, high power beams of the emitted light Lₒᵤₜ emitted by the semiconductor laser devices 1 to 4 are reflected by the beam splitter 111 and the upward deflecting mirror 113. The emitted light Lₒᵤₜ reflected by the upward deflecting mirror 113 is collected by the objective lens 114 and is made to impinge on the optical disc D. Thus, information is written in the optical disc D. Low power beams of the emitted light Lₒᵤₜ emitted by the semiconductor laser devices 1 to 4 are made to impinge on the optical disc D after passing through the optical system as described above and are thereafter reflected by the optical disc D. The resultant light or reflected light L_{ref} impinges on the light-receiving element of the signal light detector 115 after passing through the objective lens 114, the upward deflecting mirror 113, and the beam splitter 111. The reflected light is converted into electrical signals which are then processed by the signal light reproducing circuit to reproduce the information written in the optical disc D.

In this exemplary application, for example, the semiconductor laser 20 having higher heat radiating performance is disposed closer to the support base 50, and the periphery of the semiconductor laser 40 is connected to the support base 50 through the bumps 33, and 34 which have high heat conductivity. The semiconductor laser 40 having relatively low heat radiating performance may alternatively be disposed closer to the support base 50, which allows heat generated at the semiconductor laser 40 to be efficiently guided to the support base 50. As a result, it is possible to suppress a decrease in the intensity of light that the light-receiving element (not shown) can detect. In this exemplary application, since the semiconductor laser 20 has small dimensions, the material cost of the laser device can be kept low. As a result, the optical disc recording/reproducing apparatus 100 can be provided at a low cost.

Any of the semiconductor laser devices 1 to 4 which may be used as the light source can emit light beams of three wavelengths, i.e., wavelengths around 400 nm, in 600 nm, and 700 nm bands. Therefore, the apparatus can perform recording and reproduction of not only various types of existing optical discs such as CD-ROMs (Read Only Memories), CD-Rs, CD-RWs, MDs, and DVD-ROMs but also optical discs of the next generation such as Blu-ray discs. The use of such a recordable mass storage disc of the next generation makes it possible to record video data and to reproduce data thus recorded (images) with high quality and high operability.

The semiconductor laser devices 1 to 4 may be used in optical disc reproducing apparatus, optical disc recording apparatus, magneto-optical disc apparatus for recording and reproducing magneto-optical (MO) discs, and other optical apparatus in general such as optical communication apparatus. The semiconductor laser devices 1 to 4 may be used in on-vehicle apparatus which must be operable at high temperatures.

The semiconductor laser devices 1 to 4 may be formed separately from an optical system, and the devices may alternatively be formed integrally with a part of an optical system. When any of the semiconductor laser devices 1 to 4 is formed integrally with a part of an optical system, the integrated optical element (laser coupler) obtained as thus described may be incorporated in an optical apparatus or an on-vehicle apparatus.

The present application contains subject matter related to that disclosed in Japanese Priority Patent Application JP 2010-030220 filed in the Japan Patent Office on Feb. 15, 2010, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

1. An optical device comprising:
an optical element having a first light-emitting region in the vicinity of a first surface and a first metal layer in contact with at least a region of the first surface which does not face the first light-emitting region;
a support body disposed on the side of the optical element toward which the first surface faces; and
a fuse-bonding layer disposed between the first surface and the support body and in a region which does not face the first light-emitting region, the fuse-bonding layer bonding the first metal layer and the support body.

2. The optical device according to claim 1, wherein the first metal layer is also in contact with a region of the first surface facing the first light-emitting region, the first metal layer functioning as an electrode for injecting a current into the first light-emitting region.

3. The optical device according to claim 2, further comprising a platinum layer or an insulation layer in contact with a surface of the first metal layer facing the support body in a region of the surface facing the first light-emitting region.

4. The optical device according to claim 1, wherein the linear expansion coefficient of the fuse-bonding layer is greater than the linear expansion coefficients of the optical element and the support body.

5. The optical device according to claim 1, the support body includes an optical element having a second-light emitting region and a third light-emitting region in the vicinity of a second surface thereof facing the fuse-bonding layer and having a second metal layer provided on the second surface in at least a region of the second surface which does not face the second light-emitting region and the third light-emitting region.

6. The optical device according to claim 1, wherein the support body comprises an optical element, heat sink, or a sub-mount.

7. An optical device comprising:
an optical element having a light-emitting region in the vicinity of a first surface and a metal layer in contact with at least a region of the first surface facing the light-emitting region;
a support body disposed on the side of the optical element toward which the first surface faces;
a fuse-bonding layer disposed between the first surface and the support body and in at least a region facing the first light-emitting region, the fuse-bonding layer bonding the metal layer and the support body, and
an anti-distortion layer provided between the region of the first surface facing the light-emitting region and the fuse-bonding layer, the anti-distortion layer including a material having a linear expansion coefficient smaller than the linear expansion coefficient of the metal layer.

8. The optical device according to claim 7, wherein the anti-distortion layer is formed inside the metal layer or between the metal layer and the fuse-bonding layer or between the metal layer and the first surface.

9. An optical apparatus comprising:
an optical device serving as a light source, wherein the optical device includes
an optical element having a first light-emitting region in the vicinity of a first surface and a first metal layer in contact with at least a region of the first surface which does not face the first light-emitting region;
a support body disposed on the side of the optical element toward which the first surface faces; and
a fuse-bonding layer disposed between the first surface and the support body and in a region which does not face the first light-emitting region, the fuse-bonding layer bonding the first metal layer and the support body.

10. An optical apparatus comprising:
an optical device serving as a light source, wherein the optical device includes
an optical element having a light-emitting region in the vicinity of a first surface and a metal layer in contact with at least a region of the first surface facing the light-emitting region;
a support body disposed on the side of the optical element toward which the first surface faces;
a fuse-bonding layer disposed between the first surface and the support body and in at least a region facing the first light-emitting region, the fuse-bonding layer bonding the metal layer and the support body, and
an anti-distortion layer provided between the region of the first surface facing the light-emitting region and the fuse-bonding layer, the anti-distortion layer including a material having a linear expansion coefficient smaller than the linear expansion coefficient of the metal layer.
